(19) United States
(12) Patent Application Publication
(10) Pub. No.: US 2025/0389819 A1
(43) Pub. Date: Dec. 25, 2025

(54) SILICON PHOTOMULTIPLIER LINEARITY IMPROVEMENT USING BIAS CURRENT

(71) Applicant: SEMICONDUCTOR COMPONENTS INDUSTRIES, LLC, Scottsdale, AZ (US)

(72) Inventors: Stephen John BELLIS, Cobh (IE); Vincenzo SESTA, Cork (IE)

(73) Assignee: SEMICONDUCTOR COMPONENTS INDUSTRIES, LLC, Scottsdale, AZ (US)

(21) Appl. No.: 18/747,733

(22) Filed: Jun. 19, 2024

(51) Int. Cl. G01S 7/481; G01S 17/931; H03K 17/687

(52) U.S. Cl. CPC G01S 7/4816; G01S 17/931; H03K 17/6871

(57) ABSTRACT

Silicon photomultiplier linearity using bias current. A silicon photomultiplier (SiPM) device includes: a single photon avalanche detector (SPAD) configured to selectively conduct an output current in response to detecting a photon; a current source defining a microcell supply node and configured to supply the output current to the microcell supply node; and at least one active device connected between the microcell supply node and the SPAD and configured to selectively conduct the output current therebetween. The current source has a first load capacitance at the microcell supply node, and the at least one active device has a second load capacitance. The SiPM device also includes a current regulator configured to conduct a precharge current from the microcell supply node to precharge each of the first load capacitance and the second load capacitance.

### CROSS-REFERENCE TO RELATED APPLICATIONS

None.

### BACKGROUND

Many systems use light detection and ranging (LIDAR) to implement vision-like control. Such systems include weapons systems, mobile autonomous robots, safety systems for automobiles, and semi-autonomous and autonomous driving systems.

Light, such as near infrared, is directed into the scene of interest. The light propagates outward and reflects from objects within the scene. The reflected light travels back to a detection system, and based on the round trip time-of-flight of the light, the distance to objects within the scene may be determined.

LIDAR systems may use single photon avalanche detector (SPAD) or silicon photomultiplier (SiPM) devices to detect arrival of the reflected light. Avalanche detectors and silicon photomultipliers effectively apply high gain to the photon detection—in some cases a single photon may cause the avalanche breakdown within the detector, thereby creating a macroscopic output signal.

### SUMMARY

According to an aspect of the present disclosure, a silicon photomultiplier (SiPM) device is provided. The SiPM device includes: a single photon avalanche detector (SPAD) configured to selectively conduct an output current in response to detecting a photon; a current source defining a microcell supply node and configured to supply the output current to the microcell supply node; and at least one active device connected between the microcell supply node and the SPAD and configured to selectively conduct the output current therebetween. The current source has a first load capacitance at the microcell supply node, and the at least one active device has a second load capacitance. The SiPM device also includes a current regulator configured to conduct a precharge current from the microcell supply node to precharge each of the first load capacitance and the second load capacitance.

According to another aspect of the present disclosure, a light detection and ranging (LIDAR) sensor is provided. The LIDAR sensor includes: a plurality of single photon avalanche detectors (SPADs) each configured to selectively conduct an output current in response to detecting a photon; a current source defining a microcell supply node and configured to supply the output current to the microcell supply node; at least one active device connected between the microcell supply node and a SPAD of the SPADs and configured to selectively conduct the output current therebetween. At least one of the current source or the at least one active device defines a load capacitance. The LIDAR sensor also includes a current regulator configured to conduct a precharge current from the microcell supply node to precharge the load capacitance.

According to another aspect of the present disclosure, a method of operating a silicon photomultiplier (SiPM) device is provided. The method includes: selectively conducting an output current by a single photon avalanche detector (SPAD) and in response to detecting a photon; supplying the output current to the SPAD via a microcell supply node and by a current source, wherein the current source has a first load capacitance; selectively conducting, by at least one active device, the output current between the microcell supply node and the SPAD, wherein the at least one active device has a second load capacitance; and conducting, by a current regulator, a precharge current from the microcell supply node to precharge each of the first load capacitance and the second load capacitance.

These and other aspects of the present disclosure are disclosed in the following detailed description of the embodiments, the appended claims, and the accompanying figures.

### BRIEF DESCRIPTION OF THE DRAWINGS

For a detailed description of example implementations, reference will now be made to the accompanying drawings in which:

FIG. 1 shows a block diagram of a LIDAR system in accordance with at least some embodiments;

FIG. 2 shows an example LIDAR system in the form of a vehicle, in accordance with at least some embodiments;

FIG. 3 shows a block diagram of a LIDAR sensor, in accordance with at least some embodiments;

FIG. 4 shows a cross-sectional view of a Silicon Photomultiplier (SiPM) device, in accordance with at least some embodiments;

FIG. 5 shows an electrical schematic of a subpixel of a SiPM device, in accordance with at least some embodiments;

FIG. 6 shows an electrical schematic of a single photon avalanche detector (SPAD) enable/disable circuit, in accordance with at least some embodiments;

FIG. 7 shows an electrical schematic of a SPAD readout circuit, in accordance with at least some embodiments;

FIG. 8 shows an electrical schematic of a SPAD readout circuit with a precharge current regulator, in accordance with at least some embodiments;

FIG. 9 shows a schematic block diagram of a subpixel, in accordance with at least some embodiments;

FIG. 10 shows an electrical schematic of a subpixel precharge current regulator, in accordance with at least some embodiments;

FIG. 11 shows an electrical schematic of a bandgap voltage source, in accordance with at least some embodiments;

FIG. 12 shows a graph showing differential nonlinearity (DNL) as a function of a number of firing SPADs in a subpixel and without the subpixel precharge current regulator;

FIG. 13 shows a graph showing differential nonlinearity (DNL) as a function of a number of firing SPADs in a subpixel and using the subpixel precharge current regulator; and

FIG. 14 is a flow diagram showing steps in a method of operating a SiPM device, in accordance with the present disclosure.

### DEFINITIONS

Various terms are used to refer to particular system components. Different companies may refer to a component by different names—this document does not intend to distinguish between components that differ in name but not function. In the following discussion and in the claims, the terms “including” and “comprising” are used in an open-ended fashion, and thus should be interpreted to mean “including, but not limited to . . . ” Also, the term “couple” or “couples” is intended to mean either an indirect or direct connection. Thus, if a first device couples to a second device, that connection may be through a direct connection or through an indirect connection via other devices and connections.

Terms defining an elevation, such as “above,” “below,” “upper”, and “lower” shall be locational terms in reference to a direction of light incident upon a pixel array and/or an image pixel. Light entering shall be considered to interact with or pass objects and/or structures that are “above” and “upper” before interacting with or passing objects and/or structures that are “below” or “lower.” Thus, the locational terms may not have any relationship to the direction of the force of gravity.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions. To be clear, an initial reference to “a [referent]”, and then a later reference for antecedent basis purposes to “the [referent]”, shall not obviate the fact the recited referent may be plural.

In relation to electrical devices, whether stand alone or as part of an integrated circuit, the terms “input” and “output” refer to electrical connections to the electrical devices, and shall not be read as verbs requiring action. For example, a differential amplifier, such as an operational amplifier, may have a first differential input and a second differential input, and these “inputs” define electrical connections to the operational amplifier, and shall not be read to require inputting signals to the operational amplifier.

“Light” or “color” shall mean visible light ranging between about 380 and 700 nanometers. “Light” or “color” shall also mean light ranging between 700 nanometers to 800 nanometers, and invisible light, such as infrared light ranging between about 800 nanometer and 1 millimeter. “Light” or “color” shall also mean invisible light, such as ultraviolet light ranging between about 100 nanometers to 400 nanometers.

“Controller” shall mean, alone or in combination, individual circuit components, an application specific integrated circuit (ASIC), one or more microcontrollers with controlling software, a reduced-instruction-set computer (RISC) with controlling software, a digital signal processor (DSP), one or more processors with controlling software, a programmable logic device (PLD), a field programmable gate array (FPGA), or a programmable system-on-a-chip (PSOC), configured to read inputs and drive outputs responsive to the inputs.

### DETAILED DESCRIPTION

The following discussion is directed to various implementations of the invention. Although one or more of these implementations may be preferred, the implementations disclosed should not be interpreted, or otherwise used, as limiting the scope of the present disclosure, including the claims. In addition, one skilled in the art will understand that the following description has broad application, and the discussion of any implementation is meant only to be exemplary of that implementation, and not intended to intimate that the scope of the present disclosure, including the claims, is limited to that implementation.

Various examples are directed to a silicon photomultiplier (SiPM) device, which may be used in a LIDAR sensor for the automotive market. The SiPM device includes an active area that is divided into thousands of subpixels. Corresponding application specific integrated circuit (ASIC) readout circuitry may allow the subpixels to be individually addressed, thereby providing configurable active regions for SiPM output channels. Each subpixel contains a group of microcells, and each of the microcells includes a single photon avalanche detector (SPAD) and readout circuit. Examples for a 1×8 group of microcells are given, but the subpixel could be defined to be a group of 2 or more microcells in a one-dimensional or two-dimensional array.

A desirable characteristic of SiPM devices is to have a linear relationship between subpixel output current and a number of SPADs triggered by incoming photon detection or dark noise events. For instance, one SPAD triggered may cause a well-defined peak current at a subpixel output, while two SPADs triggered may provide two times the well-defined peak current at the subpixel output and so on.

When SPADs are connected to the ASIC readout circuitry, parasitic capacitances may sink charge, causing a reduction in the output current and resulting in non-linearity of a subpixel characteristic response for single photon events and also for different numbers of SPADs triggered. This can be identified as high differential non-linearity and may cause problems at the LiDAR system level, especially in detecting single photoelectron events and assessing the strength of the return signal.

The present disclosure provides a current source implemented using a bandgap and which is connected to each subpixel current regulator to bias a microcell supply node between the subpixel enable and a summing/multiplexing circuit. This biasing of the microcell supply nodes causes a reduction in an amount of charge from the SPADs that is used to charge parasitic capacitances upon a triggering event where a SPAD detects a photon. By reducing an amount of charge used to charge the parasitic capacitances, a greater amount of charge is available for measurement, upon an initial triggering event. Accordingly, the apparatus and method of the present disclosure may improve linearity of the subpixel characteristic response.

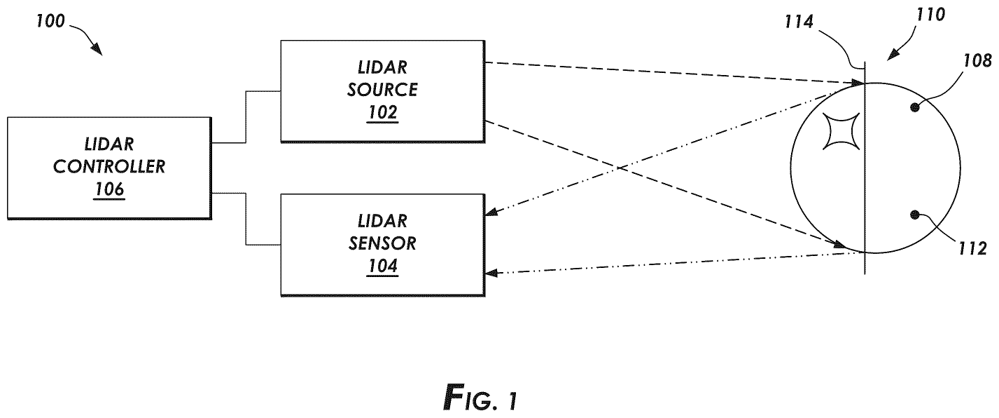

FIG. 1 shows, in block diagram form, an example LIDAR system 100. In particular, the example LIDAR system 100 comprises a LIDAR source 102, a LIDAR sensor 104, and a LIDAR controller 106. The example LIDAR source 102 is designed and constructed to direct interrogating light into a scene in front of the LIDAR source 102. The LIDAR source 102 may be any suitable source of light for use in a LIDAR system. In one example, the LIDAR source 102 comprises a single or an array of laser diodes, such as an array of vertical-cavity surface-emitting laser (VCSEL) diodes. In some cases, the light created by the LIDAR source 102 is within the visible spectrum, but in other cases the light created is outside the visible spectrum, such infrared or near infrared. In one example, the interrogating light used to illuminate the scene may be infrared having a wavelength of 905 nanometers (nm) or 1550 nm. For convenience of the discussion that follows, the light created by the LIDAR source 102 is hereafter referred to as infrared or interrogating infrared, but with the understanding that the any suitable interrogating light may be used. Turning now to the LIDAR sensor 104.

The example LIDAR sensor 104 may comprise a plurality of pixels. As will be discussed in greater detail below, the pixels of the LIDAR sensor 104 may be organized into rows and columns. When properly configured, each pixel is sensitive to the arrival of the interrogating infrared that reflects from objects within the scene. Interrogating infrared that reflects from objects within the scene is hereafter referred to as reflected infrared. Turning now to the LIDAR controller 106.

The example LIDAR controller 106 is coupled to the LIDAR source 102 to control the timing of generating and release of interrogating infrared. Moreover, the LIDAR controller 106 is coupled to the LIDAR sensor 104 such that the LIDAR controller 106 reads one or more histograms from the LIDAR sensor 104. Based on an analysis of the one or more histograms, the LIDAR controller 106 determines the combined time-of-flight of the outgoing interrogating infrared and returning reflected infrared.

The example LIDAR source 102 illuminates the scene with interrogating infrared. However, for LIDAR systems, the interrogating infrared does not necessarily simultaneously illuminate the entire scene. Rather, in the example LIDAR system 100 the LIDAR source 102 selectively illuminates the scene in particular directions, and by repetitively illuminating the scene along incrementally varying directions, ultimately the entire scene is illuminated in a piecewise fashion. The steering of the interrogating infrared may take any suitable form, such as a solid-state LIDAR source 102 that steers the interrogating infrared by selective operation of a phased array source, or a mechanical system in which the interrogating infrared is steered or directed by movable lenses and/or mirrors.

In one example, the LIDAR source 102 may illuminate the scene using a series of laser “dots” launched from the LIDAR source 102. For example, the LIDAR source 102 may be designed and constructed to generate a first interrogating infrared in the form of a dot 108. That is, the interrogating infrared is sent out in the form of a tight beam of infrared that intersects in example object within the scene, here with an example object shown as sphere 110. The dot 108 of interrogating infrared reflects back to the LIDAR sensor 104 to be used for determining the distance to the example sphere 110 at the location of the dot 108. Second interrogating infrared may be sent in the form of a second dot 112, and as before the second dot 112 of infrared reflects back to the LIDAR sensor 104. By sequentially illuminating the scene with dots of interrogating infrared, the location and distance to objects within the scene, such as the example sphere 110, may be determined. Illuminating the scene with dots of interrogating infrared may be used when the LIDAR sensor 104 is a single “row” of pixels.

In other cases, the LIDAR source 102 may illuminate the scene using lines of interrogating infrared. For example, the LIDAR source 102 may be designed and constructed to generate first interrogating infrared in the form of line 114 of infrared. That is, the interrogating infrared is sent out in the form of a line of infrared that intersects the example sphere 110 at several locations. The example line 114 of infrared is shown as a vertical line, but in other cases the line 114 may be a horizontal line, or the line 114 may sweep the example sphere 110 at any suitable angle. The line 114 of interrogating infrared reflects back to the LIDAR sensor 104 to be used for determining distance to the object in the scene at the various locations intersected by the line 114. Thereafter, further interrogating infrared may be sent in the form of additional lines at locations offset from line 114. By sequentially illuminating the scene with lines of interrogating infrared, the location and distance to the example sphere 110 may be determined. Illuminating the scene with lines of interrogating infrared may be used when the LIDAR sensor 104 has multiple rows of pixels.

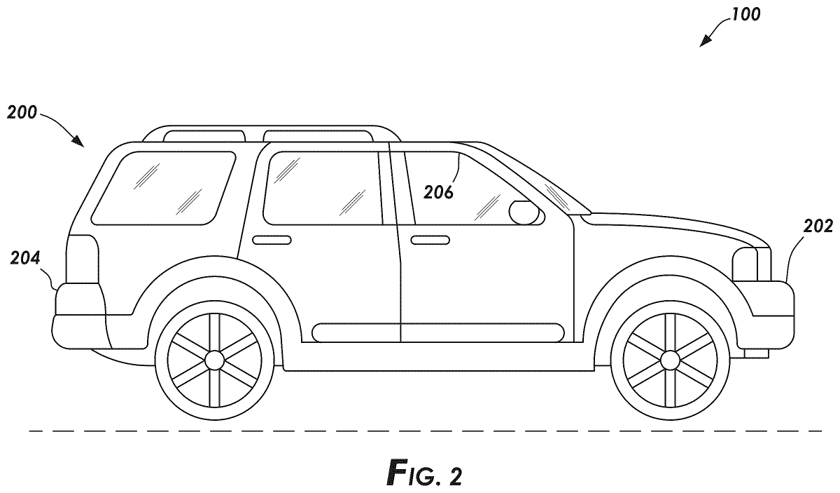

FIG. 2 shows another example of the LIDAR system 100. The LIDAR system 100 illustrated in FIG. 2 comprises an automobile or vehicle 200. The vehicle 200 is illustratively shown as a passenger vehicle, but the LIDAR system 100 may be other types of vehicles, including commercial vehicles, on-road vehicles, and off-road vehicles. Commercial vehicles may include busses and tractor-trailer vehicles. Off-road vehicles may include tractors and crop harvesting equipment. In the example of FIG. 2, the vehicle 200 includes a forward-looking LIDAR 202 arranged to capture images of scenes in front of the vehicle 200. Such forward-looking LIDAR 202 can be used for any suitable purpose, such as collision warning systems, distance-pacing cruise-control systems, autonomous driving systems, and proximity detection. The vehicle 200 further comprises a backward-looking LIDAR 204 arranged to capture images of scenes behind the vehicle 200. Such backward-looking LIDAR 204 can be used for any suitable purpose, such as collision warning systems, autonomous driving systems, proximity detection, monitoring position of overtaking vehicles, and backing up. The vehicle 200 further comprises a side-looking camera module 206 arranged to capture images of scenes beside the vehicle 200. Such side-looking camera module can be used for any suitable purpose, such as blind-spot monitoring, collision warning systems, autonomous driving systems, monitoring position of overtaking vehicles, lane-change detection, and proximity detection. In situations in which the LIDAR system 100 is a vehicle, the LIDAR controller 106 may be a controller of the vehicle 200. The discussion now turns in greater detail to the LIDAR sensor 104.

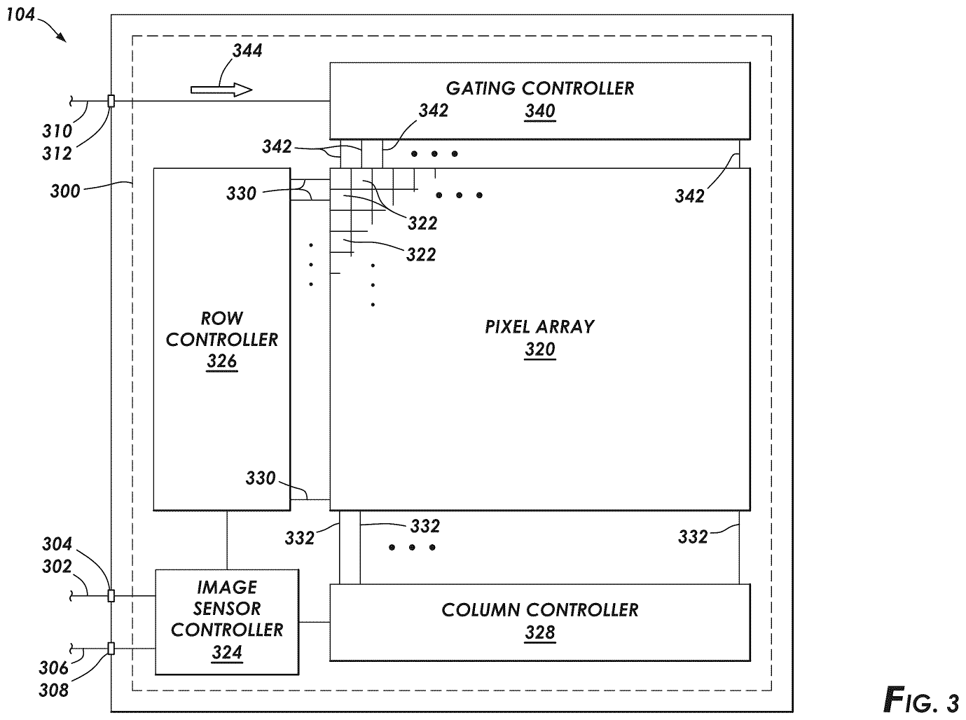

FIG. 3 shows an example LIDAR sensor 104. In particular, FIG. 3 shows that the LIDAR sensor 104 may comprise a substrate 300 of semiconductor material, such as silicon, encapsulated within packaging to create a packaged semiconductor device or packaged semiconductor product. Bond pads or other connection points of the substrate 300 couple to terminals of the LIDAR sensor 104. The connections may comprise a serial communication channel 302 coupled to terminal(s) 304, a capture input 306 coupled to terminal 308, and a phase lock input 310 coupled to terminal 312. Additional terminals will be present, such as ground, common, or power, but the additional terminals are omitted so as not to unduly complicate the figure. While a single instance of the substrate 300 is shown, in other cases multiple substrates may be combined to form the LIDAR sensor 104 in the form of a multi-chip module created before or after singulation.

The example LIDAR sensor 104 includes a pixel array 320, which may include a SiPM device. The pixel array 320 comprises a plurality of pixels, such as pixels 322 arranged in rows and columns. Pixel array 320 may comprise, for example, hundreds or thousands of rows and columns of pixels 322. Control and readout of the pixel array 320 may be implemented by an image sensor controller 324 coupled to a row controller 326 and a column controller 328. The row controller 326 may receive row addresses from the image sensor controller 324 and supply corresponding row control signals to the pixels 322, such as reset, row-select, charge transfer, and readout control signals. The row control signals may be communicated over one or more conductors, such as the row control paths 330.

Column controller 328 may be coupled to the pixel array 320 by way of one or more conductors, such as column lines 332. Column controllers may sometimes be referred to as a column control circuit, a readout circuit, or a column decoder. Column lines 332 may be used for reading out histograms from the pixels 322 and for supplying bias currents and/or bias voltages to the pixels 322. If desired, during readout operations, a pixel row in the pixel array 320 may be selected using row controller 326, and histograms generated by the pixels 322 in that pixel row can be read out along the column lines 332. The column controller 328 may include sample-and-hold circuitry for sampling and temporarily storing signals read out from the pixel array 320, amplifier circuitry, analog-to-digital conversion (ADC) circuitry, bias circuitry, column memory, latch circuitry for selectively enabling or disabling the column circuitry, or other circuitry that is coupled to one or more columns of pixels in the pixel array 320 for operating the pixels 322 and for reading out histograms from the pixel array 320. ADC circuitry in the column controller 328 may convert analog values received from the pixel array 320 into corresponding digital data. Column controller 328 may supply the histogram data to the image sensor controller 324. The image sensor controller 324 may determine the distance to reflected objects from the histogram data, or the image sensor controller 324 may supply the histogram data to the LIDAR controller 106 of FIG. 1 over the serial communication channel 302 for such determinations.

Still referring to FIG. 3, the example LIDAR sensor 104 comprises a gating controller 340. The gating controller 340 is shown in FIG. 3 as separate and distinct from the column controller 328; however, in other cases the functionality of the gating controller 340 may be incorporated within the column controller 328. The example gating controller 340 is coupled to the pixel array 320, and is designed and constructed to gate each pixel 322 of the pixel array 320 such that each pixel 322 is sensitive to reflected infrared during respective activation periods. In particular, the gating controller 340 defines the phase lock input 310, and the gating controller 340 is coupled to the pixel array 320 by way of gating paths 342. The gating controller 340 receives, by way of the phase lock input 310, a sample signal or timing signal 344 that defines a sample period. The timing signal 344 may take any suitable form, such as a square wave that defines the sample period as the period of the square wave, or a sinusoid that defines the sample period as the period of the sinusoid. By selective arrangement of the gating signals, and responsive to the timing signal 344, the gating controller 340 activates the pixels 322 of the pixel array 320 such that each pixel 322 is sensitive to reflected infrared during respective activation periods. Moreover, outside of each pixel's respective activation period, the gating controller 340 is designed and constructed to deactivate each pixel such that each pixel is insensitive to the reflected infrared. The aspects of the gating within respective activation periods are discussed more below, after introduction of an example pixel.

FIG. 4 shows an example of a cross-sectional view of a Silicon Photomultiplier (SiPM) device 400, in accordance with at least some embodiments. As shown, the SiPM device 400 includes an application-specific integrated circuit (ASIC) wafer 410 bonded to a sensor wafer 420. The sensor wafer 420 defines a plurality of SiPM microcells 422, nine of which are illustrated. The sensor wafer 420 also includes a bond pad 428 for connection to external circuitry.

Each of the SiPM microcells 422 includes a single photon avalanche detector (SPAD) 432. Each of the SPADs 432 is connected to one or more hybrid bonds 438. The hybrid bonds 438 connect the SPADs 432 to the ASIC wafer 410.

The ASIC wafer 410 includes a substrate 454 that defines a plurality of semiconductor devices 458, such as transistors which are used for readout of the SPAD sensors 432.

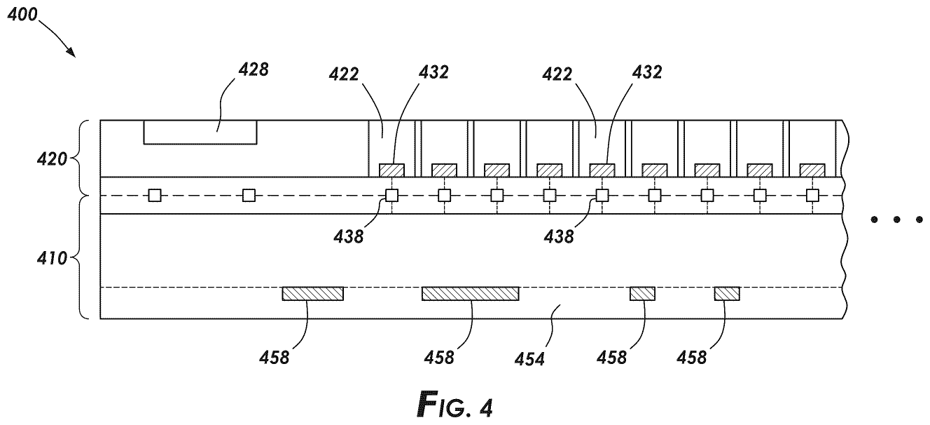

FIG. 5 shows an electrical schematic of a first subpixel 500 of an SiPM device, in accordance with at least some embodiments. A LIDAR device may include a plurality of the first subpixels 500. For example, the pixel array 320 of the example LIDAR sensor 104, may include a plurality of rows and columns of pixels 322, with each of the pixels 322 including one or more of the first subpixels 500. In some embodiments, each of the pixels 322 may include sixteen (16) of the first subpixels 500 arranged in four (4) rows and four (4) columns. However, the pixels 322 may include a different number of the first subpixels 500.

Each of the SPADs 432 located in the sensor wafer 420 has an anode 502 connected to a common reference plane 504 having a SPAD reference voltage-VBR. Each of the SPADs 432 also defines a cathode 506 that is connected to a corresponding SPAD node 514 in the ASIC wafer 410 by a corresponding one of the hybrid bonds 438.

The first subpixel 500 includes a disable/enable circuit 510 and a readout circuit 512 associated with each of the SPADs 432 of the first subpixel 500. The disable/enable circuits 510 may also be called DIS/EN circuits, for short. Each of the disable/enable circuits 510 and the readout circuits 512 is connected to a corresponding SPAD node 514. Each of the SPADs 432, in combination with a corresponding disable/enable circuit 510 and a corresponding readout circuit 512, may be called a microcell. Each of the readout circuits 512 defines a microcell supply node 516, and each of the microcell supply nodes 516 is connected to a summing and multiplexing circuit 522. The summing and multiplexing circuit 522 may function as a current source to supply a microcell current I_{SPAD} to each of the SPADs 432 via corresponding ones of the readout circuits 512. The summing and multiplexing circuit 522 may also summate the microcell currents I_{SPAD} of the first subpixel 500 to determine a number of the SPADs 432 that are triggered, thereby determining an intensity of light incident on the first subpixel 500. The summing and multiplexing circuit 522 defines an output channel 524 for communicating information regarding the light incident on the first subpixel 500 to external circuitry for LiDAR measurement. The summing and multiplexing circuit 522 is also called a summing and muxing circuit or a SUM & MUX circuit, for short. Each of the first subpixels 500 may include, for example, eight (8) of the SPADs 432. However, for simplicity of illustration, FIG. 5 shows only three of the SPADs 432 and associated circuitry.

Each of the SPADs 432 may function as a switch, selectively conducting the microcell current I_{SPAD} from a corresponding microcell supply node 516 to the common reference plane 504, upon detecting a photon.

The first subpixel 500 includes a subpixel control circuit 520 that is configured to generate several subpixel control signals, such as VPRECH, VRESET, and SUB_EN, based on a subpixel row signal 528 and a subpixel column control signal 530 from external circuitry (not shown). Each of the subpixel row signal 528 and the subpixel column control signal 530 pairs may have three control lines [0:3] to route the microcell current through the output channel. The subpixel row signal 528 and the subpixel column control signal 530 may, together, represent a unique address for each of the sixteen (16) subpixels within a pixel 322. The subpixel control signals may include a subpixel precharge signal VPRECH, a subpixel reset signal VRESET, and/or a subpixel enable signal SUB_EN. The disable/enable circuits 510 are each configured to selectively disable or enable a corresponding one of the SPADs 432 based on the subpixel precharge signal VPRECH and/or the subpixel reset signal VRESET. The readout circuits 512 are each configured to selectively conduct an output current, such as the microcell current I_{SPAD}, from the microcell supply node 516 and to the corresponding one of the SPADs 432. The readout circuits 512 may be configured to communicate the output current only when the subpixel enable signal SUB_EN is energized.

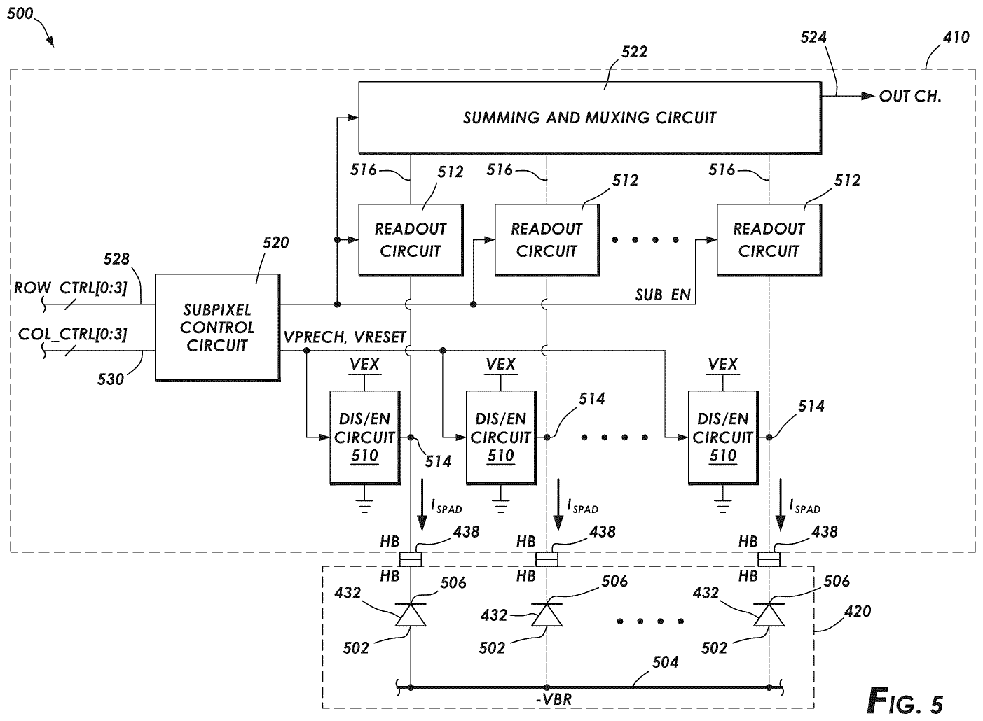

FIG. 6 shows an electrical schematic of a disable/enable circuit 510. The disable/enable circuit 510 includes a first positive-type field effect transistor (PFET) 540 and a second PFET 550 connected in series between an excitation node 532 having a pixel excitation voltage VEX and the SPAD node 514 for driving the SPAD node 514 to the pixel excitation voltage in response to the subpixel precharge signal VPRECH being energized. The pixel excitation voltage VEX may have a voltage of between about 6.2 VDC and about 6.6 VDC. In some embodiments, the pixel excitation voltage VEX on the excitation node 532 may have a nominal voltage of 6.4 VDC. The first PFET 540 defines a source 542 that is connected to the excitation node 532, a drain 544, and a gate 546 that is connected to the subpixel precharge signal VPRECH. The second PFET 550 defines a source 552 that is connected to the drain 544 of the first PFET 540, a drain 554 that is connected to the SPAD node 514, and a gate 556 that is connected to a positive supply voltage VDD, causing the second PFET 550 to be maintained in a conductive state. The series combination of the first PFET 540 and the second PFET 550 may be used to selectively conduct current where a single FET device may not be suitable, such as where the pixel excitation voltage VEX exceeds a voltage capacity of a single one of the PFET devices.

As shown, the disable/enable circuit 510 also includes a first negative-type field effect transistor (NFET) 560 and a second NFET 570 connected in series between the SPAD node 514 and a ground (GND) for driving the SPAD node 514 to a de-energized state in response to the subpixel reset signal VRESET being energized. The first NFET 560 defines a source 562, a drain 564 that is connected to the SPAD node 514, and a gate 566 that is connected to the positive supply voltage VDD, causing the first NFET 560 to be maintained in a conductive state. The second NFET 570 defines a source 572 that is connected to the ground (GND), a drain 574 that is connected to the source 562 of the first NFET 560, and a gate 576 that is connected to the subpixel reset signal VRESET. The series combination of the first NFET 560 and the second NFET 570 may be used to selectively conduct current where a single FET device may not be suitable, such as where the pixel excitation voltage VEX exceeds a voltage capacity of a single one of the NFET devices.

FIG. 7 shows an electrical schematic of a first SPAD readout circuit 600, and which may form the readout circuit 512. The first SPAD readout circuit 600 includes a quench resistor 602 having a resistance value R_{Q} and which is connected to the SPAD node 514. The first SPAD readout circuit 600 also includes a plurality of active devices for selectively enabling the microcell. The plurality of active devices includes a third PFET 610, and a fourth PFET 620 in a series configuration for selectively controlling current flow between the microcell supply node 516 and the SPAD node 514. The third PFET 610 defines a source 612 and a drain 614 that is connected to a terminal of the quench resistor 602 opposite from the SPAD node 514. The third PFET 610 also defines a gate 616 that is connected to the positive supply voltage VDD, causing the third PFET 610 to be maintained in a conductive state. The fourth PFET 620 defines a drain 624 that is connected to the source 612 of the third PFET 610, and a source 622 that is connected to the microcell supply node 516. The fourth PFET 620 also defines a gate 626 that is connected to the subpixel enable signal SUB_EN from the subpixel control circuit 520. The series combination of the third PFET 610 and the fourth PFET 620 may be used to selectively conduct current where a single FET device may not be suitable, such as where the pixel excitation voltage VEX exceeds a voltage capacity of a single one of the PFET devices.

Still referring to FIG. 7, a first load capacitance 630 is defined between the microcell supply node 516 and ground. The first load capacitance 630 may be a parasitic capacitance that is an effect of current supply circuitry in the summing and multiplexing circuit 522 and/or associated conductors between the summing and multiplexing circuit 522 and the fourth PFET 620. The first SPAD readout circuit 600 also includes a second load capacitance 632, 634, which may include parasitic capacitances of the third PFET 610, the fourth PFET 620, and/or the quench resistor 602. As shown in FIG. 7, the second load capacitance 632, 634 includes a first cascade capacitance 632 defined between the drain 624 of the fourth PFET 620 and the ground. The second load capacitance 632, 634 also includes a second cascade capacitance 634 defined between the drain 614 of the third PFET 610 and the ground. Alternatively, the second load capacitance 632, 634, may include only the second cascade capacitance 634. For example, in an alternative embodiment where the third PFET 610 and the fourth PFET 620 are combined into a single switching device, the second load capacitance 632, 634, may include only the second cascade capacitance 634 at a terminal of the quench resistor 602 opposite from the SPAD node 514.

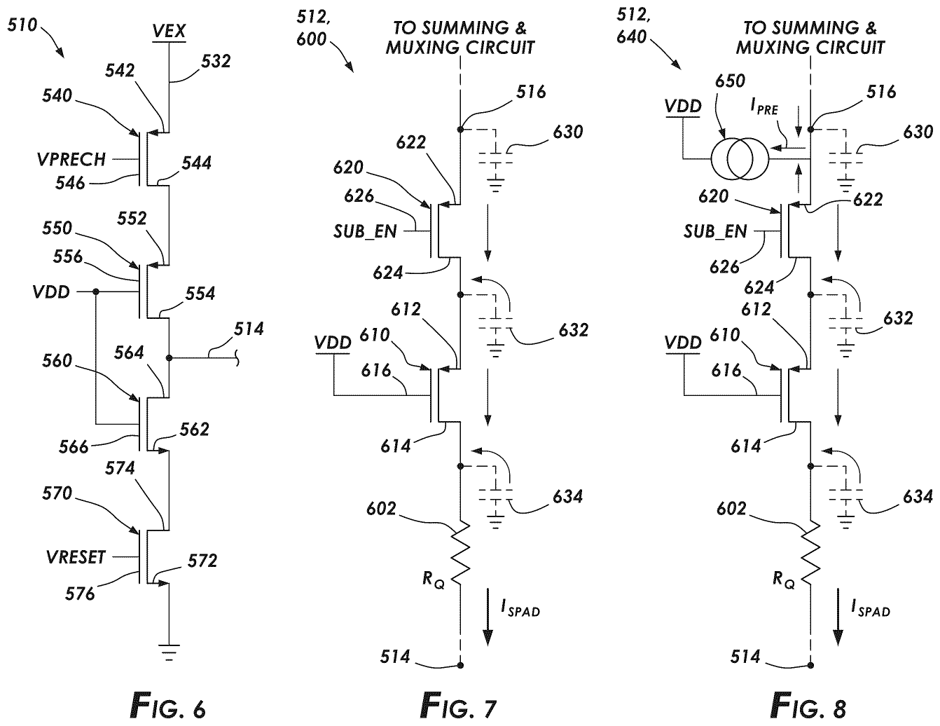

FIG. 8 shows an electrical schematic of a second SPAD readout circuit 640 in accordance with at least some embodiments of the present disclosure, and which may form the readout circuit 512. The second SPAD readout circuit 640 may be similar or identical to the first SPAD readout circuit 600, with the addition of a precharge current regulator 650. The precharge current regulator 650 is configured to conduct a precharge current I_{PRE} from the microcell supply node 516. The precharge current regulator 650 thereby functions to precharge each of the first load capacitance 630 and the second load capacitance 632, 634 before the corresponding SPAD 432 is triggered to conduct the SPAD current I_{SPAD}. Precharging the first load capacitance 630 and the second load capacitance 632, 634 reduces an amount of the SPAD current I_{SPAD} that is diverted to the first load capacitance 630 and the second load capacitance 632, 634 when the corresponding SPAD 432 is triggered. Thus, precharging the capacitances 630, 632, 634 improves linearity of the first subpixel 500 by enabling a greater amount of the SPAD current I_{SPAD} to be available to be measured by the summing and multiplexing circuit 522 when the corresponding SPAD 432 is triggered.

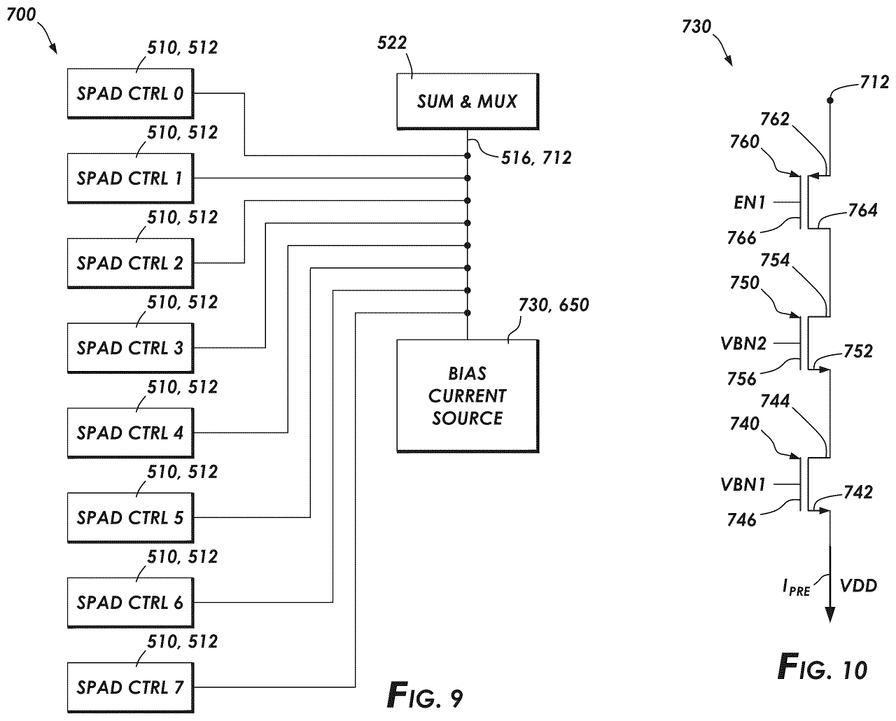

FIG. 9 shows a schematic block diagram of a second subpixel 700, in accordance with at least some embodiments. A LIDAR device may include a plurality of the second subpixels 700. For example, the pixel array 320 of the example LIDAR sensor 104, may include a plurality of rows and columns of pixels 322, with each of the pixels 322 including one or more of the second subpixels 700. The second subpixel 700 includes eight (8) SPAD microcells, each having corresponding SPAD control circuitry 510, 512 including a disable/enable circuit 510 and a readout circuit 512. The microcell supply nodes 516 of the SPAD control circuitry 510, 512 of each of the SPAD microcells in the second subpixel 700 are connected to the summing and multiplexing circuit 522 by a common input node 712. The second subpixel 700 also includes a bias current source 730 that is connected to the common input node 712. The bias current source 730 may, therefore, function as the precharge current regulator 650 for all of the microcells connected thereto. The bias current source 730 may, therefore, precharge the capacitances 630, 632, 634, thus improving linearity of the second subpixel 700.

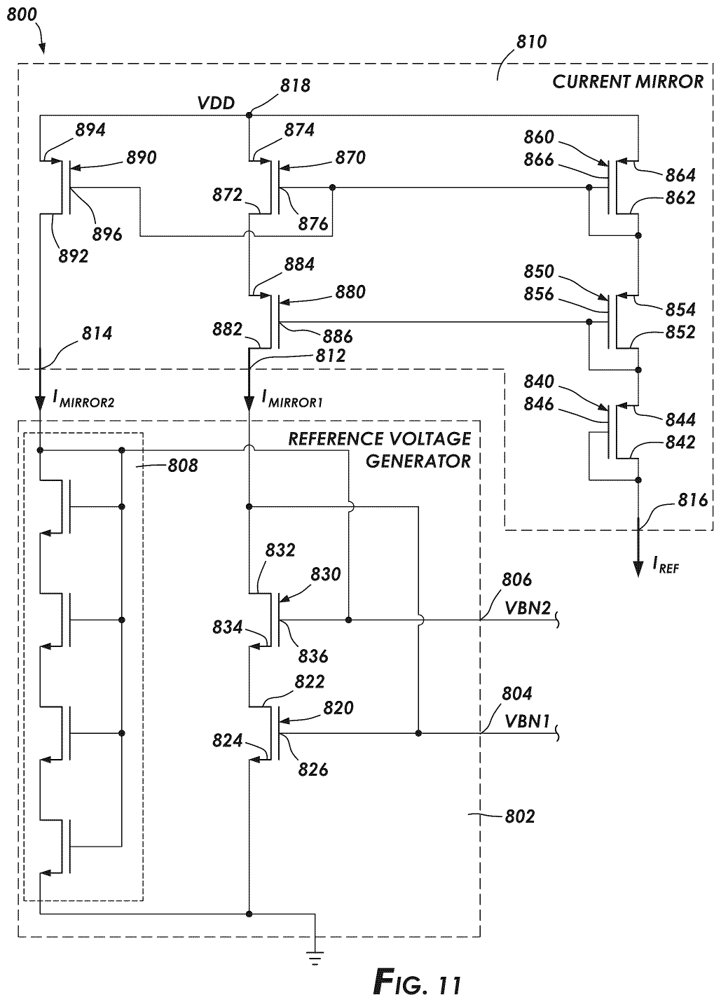

FIG. 10 shows an electrical schematic of the bias current source 730, in accordance with at least some embodiments. The bias current source 730 uses a bandgap voltage to regulate the precharge current I_{PRE}. The bias current source 730 includes a series combination of a third NFET 740, a fourth NFET 750, and a fifth PFET 760, connected between the positive supply voltage VDD and the common input node 712. The third NFET 740 defines a source 742 connected to the positive supply voltage VDD, and a drain 744. The third NFET 740 also defines a gate 746 having a first reference voltage VNB1 from a bandgap voltage source. The fourth NFET 750 defines a source 752 that is connected to the drain 744 of the third NFET 740, and a drain 754. The fourth NFET 750 also defines a gate 756 having a second reference voltage VNB2 from the bandgap voltage source. The fifth PFET 760 includes a source 762 that is connected to the common input node 712, and a drain 764 that is connected to the drain 754 of the fourth NFET 750. The fifth PFET 760 also defines a gate 766 that is connected to an external circuit (not shown) for receiving an enable signal EN1 for selectively enabling the bias current source 730.

FIG. 11 shows an electrical schematic of a bandgap voltage source 800, in accordance with at least some embodiments. The bandgap voltage source 800 is configured to generate the first reference voltage VNB1 and the second reference voltage VNB2 for application to the bias current source 730 to regulate the precharge current I_{PRE}. The bandgap voltage source 800 includes a reference voltage generator 802 and a current mirror 810. The reference voltage generator 802 defines a first output node 804 having the first reference voltage VNB1, and which may be connected to the bias current source 730. The reference voltage generator 802 also defines a second output node 806 having the second reference voltage VNB2, and which may be connected to the bias current source 730. The current mirror 810 defines a first current supply node 812, a second current supply node 814, a mirrored node 816, and a power node 818.

The reference voltage generator 802 includes a resistance 808 connected between the second current supply node 814 and the ground GND. The reference voltage generator 802 may, thereby generate the second reference voltage VNB2 by conducting at least a portion of the second mirror current I_{MIRROR2} through the resistance 808. Depending on a type of load connected to the second output node 806, substantially all of the second mirror current I_{MIRROR2} may be conducted through the resistance 808. The resistance 808 includes four NFETs in a series configuration. However, the resistance 808 may include a different construction to provide a desired amount of resistance. Each of the four NFETs of the resistance 808 defines a drain and a source, with a drain of one of the four NFETs connected to the second current supply node 814, and a source of an opposite one of the four NFETs connected to the ground GND. Each of the four NFETs of the resistance 808 also defines a gate that is connected to the second current supply node 814.

The reference voltage generator 802 also includes a fifth NFET 820 defining a drain 822 and a source 824 that is connected to the ground GND. The fifth NFET 820 also defines a gate 826 that is connected to the first output node 804. The reference voltage generator 802 also includes a sixth NFET 830 defining a drain 832 that is connected to the first current supply node 812, and a source 834 that is connected to the drain 822 of the fifth NFET 820. The sixth NFET 830 also defines a gate 836 that is connected to the second output node 806. The reference voltage generator 802 may, thereby generate the first reference voltage VNB1 by conducting at least a portion of the first mirror current I_{MIRROR1} through the series combination of the fifth NFET 820 and the sixth NFET 830. Depending on a type of load connected to the first output node 804, substantially all of the first mirror current I_{MIRROR1} may be conducted through the series combination of the fifth NFET 820 and the sixth NFET 830.

The current mirror 810 includes a plurality of PFETs 840, 850, 860, 870, 880, 890 and is configured to supply the first mirror current I_{MIRROR1} via the first current supply node 812 and the second mirror current I_{MIRROR2} via the second current supply node 814. In some embodiments, the current mirror 810 may regulate each of the first mirror current I_{MIRROR1} and the second mirror current I_{MIRROR2} to be equal to the reference current I_{REF} at the mirrored node 816. The reference current I_{REF} may be generated by an external source (not shown), which may be located elsewhere on the ASIC wafer 410. Alternatively, or additionally, some or all of the external source may be implemented using components external from the ASIC wafer 410.

The current mirror 810 includes a sixth PFET 840 that defines a drain 842, a source 844, and a gate 846. The drain 842 and the gate 846 of the sixth PFET 840 are each connected to the mirrored node 816. The current mirror 810 also includes a seventh PFET 850 that defines a drain 852, a source 854, and a gate 856. The drain 852 and the gate 856 of the seventh PFET 850 are each connected to the source 844 of the sixth PFET 840. The current mirror 810 also includes an eighth PFET 860 that defines a drain 862, a source 864, and a gate 866. The drain 862 and the gate 866 of the eighth PFET 860 are each connected to the source 854 of the seventh PFET 850, and the source 864 of the eighth PFET 860 is connected to the power node 818 having the positive supply voltage VDD.

The current mirror 810 also includes a ninth PFET 870 that defines a drain 872, a source 874, and a gate 876 that is connected to the gate 866 of the eighth PFET 860. The source 874 of the ninth PFET 870 is connected to the power node 818 having the positive supply voltage VDD. The current mirror 810 also includes a tenth PFET 880 that defines a drain 882, a source 884, and a gate 886 that is connected to the gate 856 of the seventh PFET 850. The drain 882 of the tenth PFET 880 is connected to the first current supply node 812, and the source 884 of the tenth PFET 880 is connected to the drain 872 of the ninth PFET 870. The current mirror 810 also includes an eleventh PFET 890 that defines a drain 892, a source 894, and a gate 896 that is connected to the gate 866 of the eighth PFET 860. The source 894 of the eleventh PFET 890 is connected to the power node 818 having the positive supply voltage VDD, and the drain 892 of the eleventh PFET 890 is connected to the second current supply node 814.

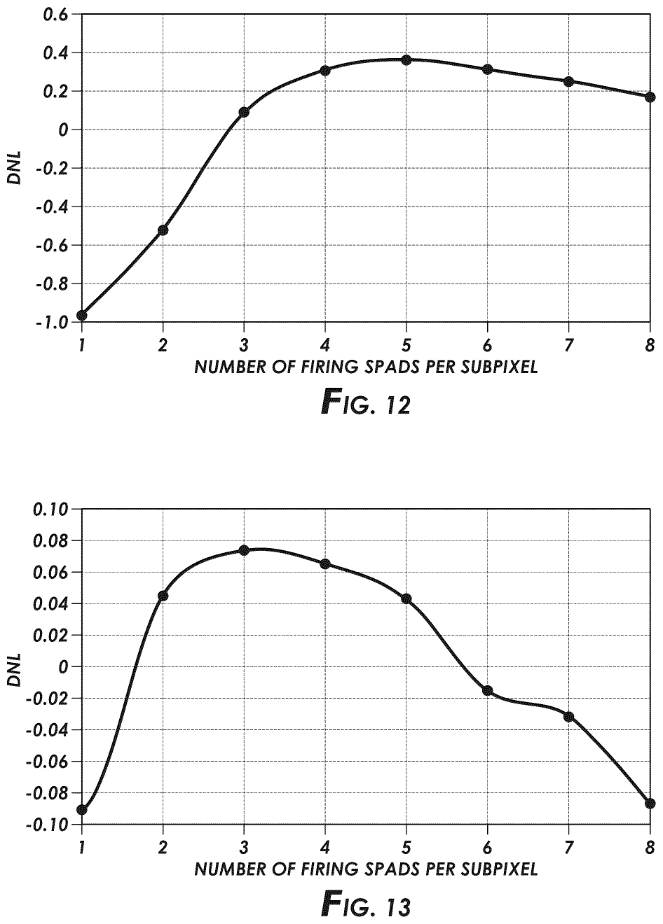

FIG. 12 shows a graph showing differential nonlinearity (DNL) as a function of a number of firing SPADs in a subpixel with a pixel excitation voltage VEX of 6.4V, a temperature of 25 C, and without the precharge current regulator 650 being active. As shown in FIG. 12, a single photo-electron (SPE) event resulting in one SPAD being triggered corresponds to a DNL value of −0.9629, which represents a relatively large non-linear characteristic response.

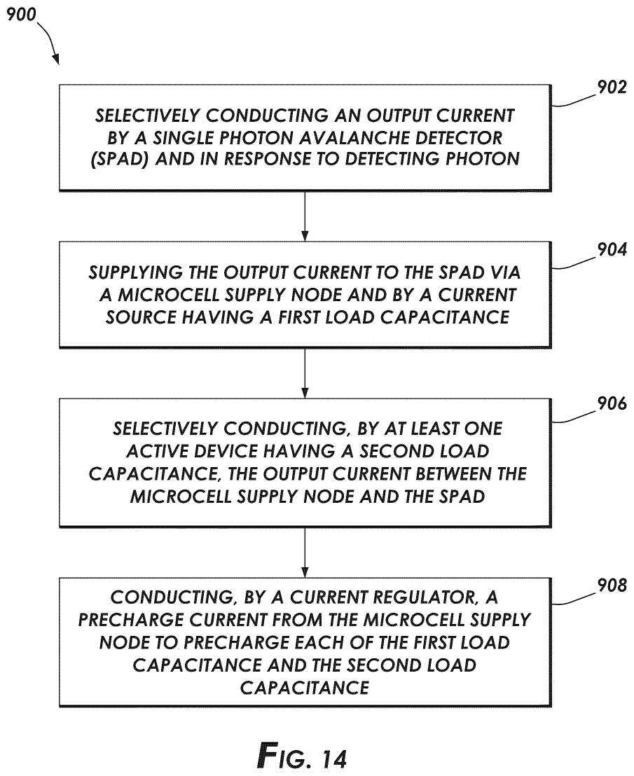

FIG. 13 shows a graph showing differential nonlinearity (DNL) as a function of a number of firing SPADs in a subpixel with a pixel excitation voltage VEX of 6.4V, a temperature of 25 C, and with the precharge current regulator 650 being active, generating a current of 1 μA per subpixel 700. A single photo-electron (SPE) event resulting in one SPAD being triggered may generate a peak current of 14.8 μA, which is very close to an average of the current steps of 16.3 μA, corresponding to a low DNL. As shown in the graph of FIG. 13, the precharge current regulator 650 of the present disclosure causes the DNL for a SPE event have a value of about −0.09. This is approximately a tenfold reduction in DNL for a SPE event.

FIG. 14 is a flow diagram showing steps in a method 900 of operating a Silicon Photomultiplier (SiPM) device, in accordance with the present disclosure. For simplicity of explanation, the method 900 is depicted in FIG. 14 and described as a series of operations. However, the operations can occur in various orders and/or concurrently, and/or with other operations not presented and described herein.

The method 900 includes selectively conducting an output current by a single photon avalanche detector (SPAD) and in response to detecting a photon, at step 902. For example, each of the SPADs 432 may selectively conduct the microcell current I_{SPAD} in response to being triggered by a photon.

The method 900 also includes supplying the output current to the SPAD via a microcell supply node and by a current source having a first load capacitance, at step 904. For example, the summing and multiplexing circuit 522 may function as the current source to supply the microcell currents I_{SPAD} to each of the SPADs 432 via corresponding ones of the microcell supply nodes 516. The current source may define the first load capacitance at the microcell supply node. For example, the current source, including the summing and multiplexing circuit 522, may define the first load capacitance 630 between the microcell supply node 516 and the ground GND.

The method 900 also includes selectively conducting, by at least one active device having a second load capacitance, the output current between the microcell supply node and the SPAD, at step 906. For example, the third PFET 610 and/or the fourth PFET 620 may function to selectively conduct the microcell current I_{SPAD} between the microcell supply node 516 and a corresponding one of the SPADs 432. The at least one active device may define the second load capacitance. For example, the second load capacitance may include one or more of the first cascade capacitance 632 and/or the second cascade capacitance 634.

In some embodiments, step 906 includes selectively conducting the output current by two field effect transistors (FETs) in a series configuration. For example, the third PFET 610 and the fourth PFET 620 may operate in conjunction to selectively conduct the microcell current I_{SPAD} between the microcell supply node 516 and a corresponding one of the SPADs 432.

The method 900 also includes conducting, by a current regulator, a precharge current from the microcell supply node to precharge each of the first load capacitance and the second load capacitance, at step 908. For example, the precharge current regulator 650 may function to conduct the precharge current I_{PRE} from the microcell supply node 516, thereby precharging each of the first load capacitance 630 and the second load capacitance 632, 634.

In some embodiments, the SPAD is one of a plurality of SPADs, and the method further includes determining a number of the plurality of SPADs in a triggered state based on a sum of the output currents. For example, the summing and multiplexing circuit 522 may also summate the microcell currents I_{SPAD} of the first subpixel 500 to determine a number of the plurality of SPADs in the triggered state and to thereby determine an intensity of light incident on the first subpixel 500.

In some embodiments, the method 900 further includes regulating the precharge current using a bias current source and a bandgap voltage source. For example, the bias current source 730 of the present disclosure may regulate the precharge current I_{PRE} using the first reference voltage VNB1 and the second reference voltage VNB2 from the bandgap voltage source 800.

In some embodiments, regulating the precharge current using the bias current source and a bandgap voltage source further includes: conducting and regulating the precharge current by the bias current source including a first field effect transistor (FET) and a second FET in series with the first FET; generating a first reference voltage and a second reference voltage by the bandgap voltage source; and applying the first reference voltage to a gate of the first FET of the bias current source; and applying the second reference voltage to a gate of the second FET of the bias current source. For example, the bias current source 730, including the third NFET 740 in series with the fourth NFET 750, may conduct and regulate the precharge current I_{PRE}. The bandgap voltage source 800 may generate the first reference voltage VNB1, which may be applied to the gate 746 of the third NFET 740 of the bias current source 730. The bandgap voltage source 800 may also generate the second reference voltage VNB2, which may be applied to the gate 756 of the fourth NFET 750 of the bias current source 730.

In some embodiments, generating the first reference voltage and the second reference voltage further includes: supplying a first mirror current via a first current supply node and based on a reference current through a mirrored node; supplying a second mirror current via a second current supply node and based on the reference current at the mirrored node; generating the first reference voltage by conducting the first mirror current through a first output FET and a second output FET connected in series and between the first current supply node and a ground; and generating the second reference voltage by conducting the second mirror current through a resistance between the second current supply node and the ground. For example, the current mirror 810 may supply the first mirror current I_{MIRROR1} via the first current supply node 812 and based on the reference current I_{REF} at the mirrored node 816. The current mirror 810 may also supply the second mirror current I_{MIRROR2} via the second current supply node 814 and based on the reference current I_{REF} at the mirrored node 816. The reference voltage generator 802 may generate the first reference voltage VBN1 by conducting some or all of the first mirror current I_{MIRROR1} through the series combination of the fifth NFET 820 and the sixth NFET 830, between the first current supply node 812 and the ground GND. The reference voltage generator 802 may also generate the second reference voltage VBN2 by conducting some or all of the second mirror current I_{MIRROR2} through the resistance 808 and between the second current supply node 814 and the ground GND.

In some embodiments, the current mirror 810 may regulate each of the first mirror current I_{MIRROR1} and the second mirror current I_{MIRROR2} to be equal to the reference current I_{REF} at the mirrored node 816.

Many of the electrical connections in the drawings are shown as direct couplings having no intervening devices, but not expressly stated as such in the description above. Nevertheless, this paragraph shall serve as antecedent basis in the claims for referencing any electrical connection as “directly coupled” for electrical connections shown in the drawing with no intervening device(s).

The above discussion is meant to be illustrative of the principles and various implementations of the present invention. Numerous variations and modifications will become apparent to those skilled in the art once the above disclosure is fully appreciated. It is intended that the following claims be interpreted to embrace all such variations and modifications.

What is claimed is:

1. A silicon photomultiplier (SiPM) device, comprising:
a single photon avalanche detector (SPAD) configured to selectively conduct an output current in response to detecting a photon;
a current source defining a microcell supply node and configured to supply the output current to the microcell supply node, the current source having a first load capacitance at the microcell supply node;
at least one active device connected between the microcell supply node and the SPAD and configured to selectively conduct the output current therebetween, the at least one active device having a second load capacitance; and
a current regulator configured to conduct a precharge current from the microcell supply node to precharge each of the first load capacitance and the second load capacitance.

2. The silicon photomultiplier (SiPM) device of claim 1, wherein the at least one active device includes two field effect transistors (FETs) in a series configuration.

3. The silicon photomultiplier (SiPM) device of claim 1, wherein the SPAD is one of a plurality of SPADs, and
wherein the current source is configured to determine a number of the plurality of SPADs in a triggered state based on a sum of the output currents.

4. The silicon photomultiplier (SiPM) device of claim 3, wherein each SPAD of the plurality of SPADs is connected to the microcell supply node for conducting the output current therefrom.

5. The silicon photomultiplier (SiPM) device of claim 1, wherein the current regulator includes a bias current source using a bandgap voltage to regulate the precharge current.

6. The silicon photomultiplier (SiPM) device of claim 1, wherein the current regulator includes a first field effect transistor (FET) and a second FET in series with the first FET for regulating the precharge current,
wherein the first FET defines a gate having a first reference voltage, and
wherein the second FET defines a gate having a second reference voltage.

7. The silicon photomultiplier (SiPM) device of claim 6, wherein the current regulator further includes a reference voltage generator configured to generate each of the first reference voltage and the second reference voltage,
wherein the reference voltage generator includes a first output FET connected in series with a second output FET,
wherein the first output FET defines a gate having the first reference voltage,
wherein the second output FET defines a gate having the second reference voltage.

8. The silicon photomultiplier (SiPM) device of claim 7, wherein the current regulator further includes a current mirror having a mirrored node and a first current supply node,
wherein the current mirror is configured to supply a first mirror current via the first current supply node and based on a reference current at the mirrored node,
wherein the first output FET and the second output FET of the reference voltage generator are connected in series between the first current supply node of the current mirror and a ground, and
wherein the first current supply node is directly connected to the gate of the first output FET and having the first reference voltage.

9. The silicon photomultiplier (SiPM) device of claim 8, wherein the current mirror is configured to supply a second mirror current via a second current supply node and based on the reference current at the mirrored node, and
wherein the reference voltage generator further includes a resistance connected between the second current supply node and the ground; and
wherein the second current supply node is directly connected to the gate of the second output FET and having the second reference voltage.

10. A light detection and ranging (LIDAR) sensor, the sensor comprising:
a plurality of single photon avalanche detectors (SPADs) each configured to selectively conduct an output current in response to detecting a photon;
a current source defining a microcell supply node and configured to supply the output current to the microcell supply node;
at least one active device connected between the microcell supply node and a SPAD of the SPADs and configured to selectively conduct the output current therebetween,
wherein at least one of the current source or the at least one active device defines a load capacitance; and
a current regulator configured to conduct a precharge current from the microcell supply node to precharge the load capacitance.

11. The LIDAR sensor of claim 10, wherein the at least one active device includes two field effect transistors (FETs) in a series configuration.

12. The LIDAR sensor of claim 10, wherein the current source is configured to determine a number of the plurality of SPADs in a triggered state based on a sum of the output currents.

13. The LIDAR sensor of claim 10, wherein the current regulator includes a bias current source using a bandgap voltage to regulate the precharge current.

14. A vehicle including the LIDAR sensor of claim 10.

15. A method of operating a silicon photomultiplier (SiPM) device, the method comprising:
selectively conducting an output current by a single photon avalanche detector (SPAD) and in response to detecting a photon;
supplying the output current to the SPAD via a microcell supply node and by a current source, wherein the current source has a first load capacitance;
selectively conducting, by at least one active device, the output current between the microcell supply node and the SPAD, wherein the at least one active device has a second load capacitance; and
conducting, by a current regulator, a precharge current from the microcell supply node to precharge each of the first load capacitance and the second load capacitance.

16. The method of claim 15, wherein selectively conducting the output current between the microcell supply node and the SPAD includes selectively conducting the output current by two field effect transistors (FETs) in a series configuration.

17. The method of claim 15, wherein the SPAD is one of a plurality of SPADs, and
wherein the method further includes determining a number of the plurality of SPADs in a triggered state based on a sum of the output currents.

18. The method of claim 15, further including regulating the precharge current using a bias current source and a bandgap voltage source.

19. The method of claim 18, wherein regulating the precharge current using the bias current source and the bandgap voltage source further includes:
conducting and regulating the precharge current by the bias current source including a first field effect transistor (FET) and a second FET in series with the first FET;
generating a first reference voltage and a second reference voltage by the bandgap voltage source;
applying the first reference voltage to a gate of the first FET of the bias current source; and
applying the second reference voltage to a gate of the second FET of the bias current source.

20. The method of claim 19, wherein generating the first reference voltage and the second reference voltage further includes:
supplying a first mirror current via a first current supply node and based on a reference current through a mirrored node;
supplying a second mirror current via a second current supply node and based on the reference current at the mirrored node;
generating the first reference voltage by conducting the first mirror current through a first output FET and a second output FET connected in series and between the first current supply node and a ground; and
generating the second reference voltage by conducting the second mirror current through a resistance between the second current supply node and the ground.
